(19) United States
(12) Patent Application Publication
(10) Pub. No.: US 2007/0200225 A1
(43) Pub. Date: Aug. 30, 2007

(54) Heat sink for semiconductor package

(76) Inventors: Ruzaini Ibrahim, Selangor (MY); Kong Bee Tiu, Selangor (MY); Kesvakumar V.C. Muniandy, Selangor (MY)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/364,048

(22) Filed: Feb. 28, 2006

(51) Int. Cl. H01L 23/34

(52) U.S. Cl. 257/712

(57) ABSTRACT

A heat sink (10) for a semiconductor package (38) includes a top surface (12) having a recessed hole (16) at its center. A sidewall (14) formed around the top surface (12) of the heat sink (10) has gaps (18) formed in the sidewall (14). An air vent (22) is formed at a corner of the heat sink (10). The heat sink (10) is used for center gate molding. Mold compound (24) enters the recessed hole (16), covers an IC die 30, and exits via the gaps (18). During mold injection, air escapes through the air vent (22).

### BACKGROUND OF THE INVENTION

The present invention relates to the packaging of integrated circuits (ICs) and more particularly to a heat sink for a semiconductor package.

With the advances in wire bonding technology, semiconductor assemblers are now able to manufacture semiconductor packages with finer pitches and more complex wiring schemes. However, fine pitch applications and those involving long wires are susceptible to wire sweep during molding. Wire sweep is undesirable as it can affect the electrical performance of a package and can cause package failure.

Tests have shown that wire sweep during molding can be reduced by using a center or top gate molding process, instead of a conventional edge gate molding process. However, thermal management of center gate molded packages is likely to pose a problem as conventional heat sinks are typically designed for edge gate molding processes, and are therefore not suited for use in center gate molding processes. For example, due to the radial flow pattern of the mold compound in a center gate molding process, air tends to get trapped at the sides of the conventional heat sink. The trapped air shows up as voids in the resultant semiconductor packages. The presence of voids reduces the reliability of the packages and can cause package defects, thereby lowering the yield of such packages. Thus, a need exists for a heat sink for center gate molded semiconductor packages.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged perspective view of a heat sink in accordance with an embodiment of the present invention;

FIG. 2 is an enlarged top plan view of the heat sink of FIG. 1;

FIG. 3 is an enlarged cross-sectional view of the heat sink of FIG. 1;

FIG. 4 is an enlarged cross-sectional view of a semiconductor assembly placed in a mold cavity in accordance with an embodiment of the present invention;

FIG. 5 is an enlarged cross-sectional view of the semiconductor assembly along the line X-X in FIG. 4;

FIG. 6 is an enlarged top plan view of the semiconductor assembly of FIG. 4 being encapsulated by a mold compound;

FIG. 7 is an enlarged top plan view of a semiconductor package formed out of the encapsulated semiconductor assembly of FIG. 6; and

FIG. 8 is an enlarged cross-sectional view of the semiconductor package of FIG. 7.

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

The present invention provides a heat sink for a semiconductor package. The heat sink includes a top surface having a recessed hole proximate to a center thereof, and at least one vent proximate to a corner of the heat sink.

The present invention also provides a heat sink for a semiconductor package including a top surface having a recessed hole proximate to a center thereof. A sidewall is formed around the top surface of the heat sink. A plurality of gaps is formed in the sidewall. The heat sink includes at least one vent proximate to a corner thereof.

The present invention further provides a semiconductor package including a substrate and an integrated circuit (IC) die attached and electrically connected to the substrate. A heat sink is placed over the IC die and is attached to the substrate. The heat sink includes a top surface having a recessed hole proximate to a center thereof and at least one vent proximate to a corner of the heat sink.

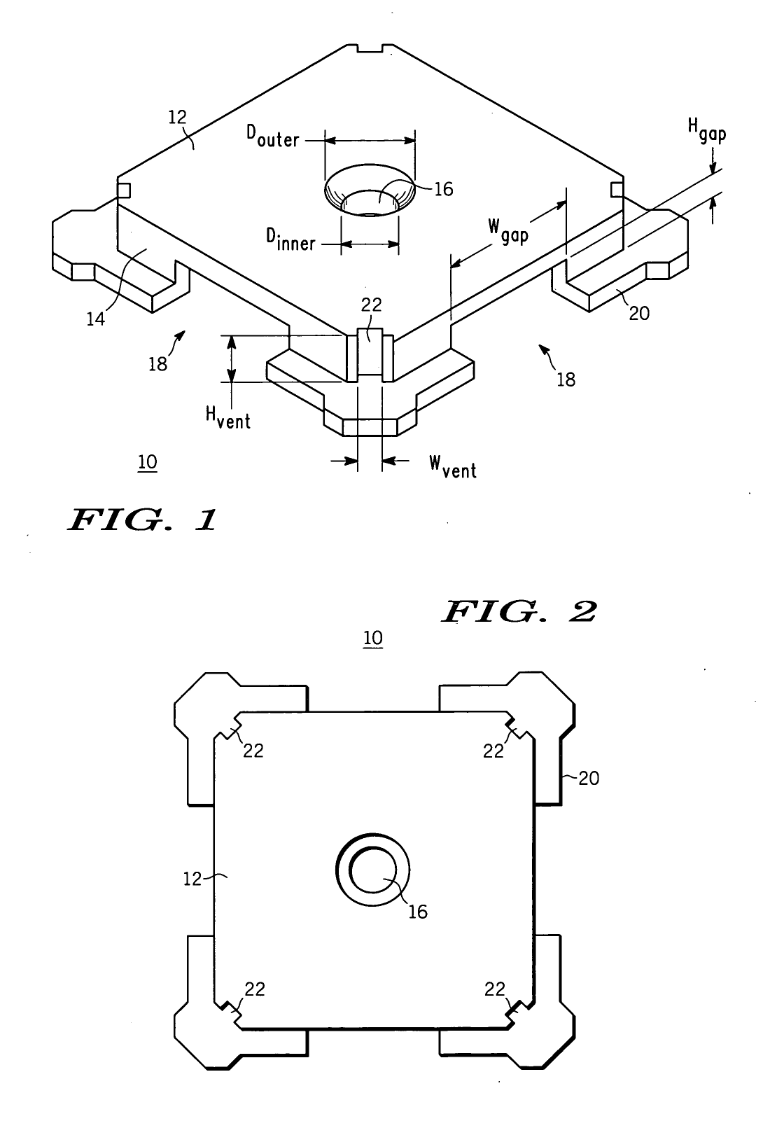

FIGS. 1 to 3 show a heat sink 10 in accordance with an embodiment of the present invention.

Referring now to FIG. 1, an enlarged perspective view of the heat sink 10 is shown. The heat sink 10 has a top surface 12 and a sidewall 14 formed around the top surface 12. The heat sink 10 generally is sized and shaped to fit over a semiconductor integrated circuit (IC). For example, for a square shaped IC measuring 5 mm by 5 mm, the heat sink 10 is square shaped too and in one embodiment measures about 20 mm by about 20 mm. Sizing the heat sink 10 greater than the IC allows room for wire bonds and encapsulation. Moreover, the size of the heat sink 10 allows for good placement tolerance. The heat sink 10 may be made of copper or other thermally conductive material known in the art.

The top surface 12 includes a recessed hole 16 proximate to a center thereof. The hole 16 facilitates center gate molding, while the recess in the hole 16 reduces bleeding or flashing of a mold compound during encapsulation. The mechanism by which the reduction in bleeding or flashing is achieved is described below with reference to FIG. 8. In one embodiment, the hole 16 has an outer circumferential diameter Dₒᵤₜₑᵣ of about 4.0˜5.0 mm and an inner circumferential diameter Dᵢₙₙₑᵣ of about 1.5˜2.0 mm. In the embodiment shown in FIG. 1, the hole is circular in shape. However, those of skill in the art will understand that the present invention is not limited by the size or the shape of the hole 16. The recessed hole 16 may be formed by cutting or punching.

A plurality of gaps 18 is formed in the sidewall 14 and a base 20 is formed at a distal end of the sidewall 14. As can be seen, the gaps 18 are formed along respective sides of the heat sink 10. The gaps 18 permit the flow of a mold compound out from under the heat sink 10 during encapsulation. In the embodiment shown, the gaps 18 are rectangular in shape, for example, having a width W_{gap} of about 6.0 mm to about 7.0 mm and a height H_{gap} of about 0.5 mm. Nonetheless, it should be understood that the present invention is not limited by the shape or the dimensions of the gaps 18. The gaps 18 may be formed by cutting or punching.

The heat sink 10 includes at least one vent 22 proximate to a corner thereof. The vent 22 facilitates the release of the air from beneath the top surface 12 of the heat sink 10 during the mold encapsulation process and is sized to restrict the flow of a mold compound therethrough during encapsulation. For example, the vent 22 may have a height Hᵥₑₙₜ of about 0.5 mm to about 0.8 mm and a width Wᵥₑₙₜ of about 1.0 mm to about 1.5 mm. In the embodiment shown, the vent 22 is rectangular in shape and extends from the top surface 12 of the heat sink 10 to the base 20. Nonetheless, it should be understood that the present invention is not limited by the dimensions or the shape of the vent 22.

Referring now to FIG. 2, an enlarged top plan view of the heat sink 10 is shown. As can be seen, a plurality of the vents 22 is formed in the respective corners of the heat sink 10. The formation of more than one vent 22 in the heat sink 10 is preferred as the vents 22 facilitate release of the air from beneath the top surface 12 of the heat sink 10. Accordingly, the likelihood of air being trapped under the top surface 12 of the heat sink 10 is reduced by the provision of a greater numbers of vents 22. This in turn reduces the number of voids formed in the resultant semiconductor package. Nonetheless, it should be understood that the present invention is not limited by the number of vents 22 in the heat sink 10. The vents 22 may be formed by cutting or punching. Etching is also possible, but not economical.

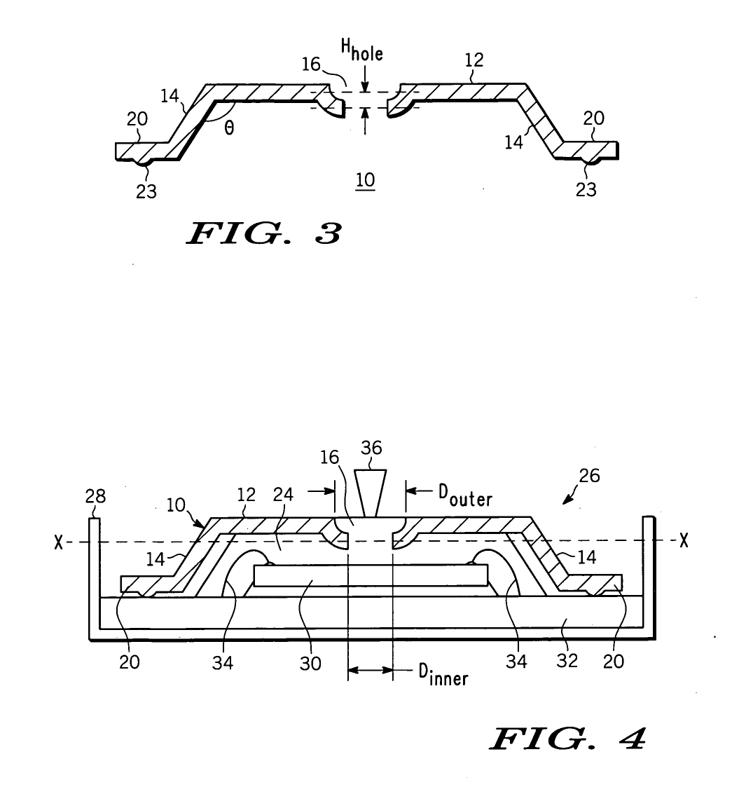

Referring now to FIG. 3, an enlarged cross-sectional view of the heat sink 10 is shown. In this particular embodiment, the recessed hole 16 has a depth Hₕₒₗₑ of about 40 to 50 microns. However, it should be understood that the present invention is not limited by the depth Hₕₒₗₑ of the recessed hole 16. As previously mentioned, the recess in the hole 16 reduces bleeding or flashing of a mold compound during encapsulation. The sidewall 14 of the heat sink 10 shown in FIG. 3 is not perpendicular to the top surface 12 of the heat sink 10, although it could be perpendicular. In the embodiment shown, the sidewall 14 extends at an angle θ of between about 120° to about 135° from the top surface 12 of the heat sink 10. The base 20 may include one or more bumps 23 or dimples on an underside thereof. The bumps 23 enhance the attachment of the heat sink to a substrate when the attachment material (e.g., epoxy) is dispensed on the substrate at locations that coincide with the bumps 23. The bumps 23 also help to maintain planarity of the heat sink. The bumps 23 may be formed by a downsetting/pressing process.

FIGS. 4 to 7 show the flow of a mold compound 24 during a center gate molding process to encapsulate a semiconductor assembly 26, the semiconductor assembly 26 including the heat sink 10 of FIGS. 1 to 3.

Referring now to FIG. 4, the semiconductor assembly 26 is placed in a mold cavity 28 as shown. The semiconductor assembly 26 comprises an integrated circuit (IC) die 30 attached and electrically connected to a substrate 32. The IC die 30 is of a type well known to those of ordinary skill in the art, such as processor chips, application specific integrated circuits (ASIC), etc., and further description of these components is not required for a complete understanding of the present invention. The IC die 30 is attached to the substrate 32 in a known manner, such as with an adhesive material layer or an adhesive tape, and is electrically connected to the substrate 32 via a plurality of wires 34. The wires 34 may be made of gold (Au), copper (Cu), aluminium (Al) or other electrically conductive materials as are known in the art and commercially available.

The heat sink 10 is placed over the IC die 30 and is attached to the substrate 32. More particularly, the base 20 of the heat sink 10 is attached to the substrate 32. The heat sink 10 is attached to the substrate 32 with an adhesive or in any other known manner using existing equipment and processes.

The mold compound 24 is dispensed via a center or top gate 36 and flows through the hole 16 in the top surface 12 of the heat sink 10 to fill the mold cavity 28. The mold compound 24 thus enters the hole 16 and spreads outwardly over the top of the IC die 30.

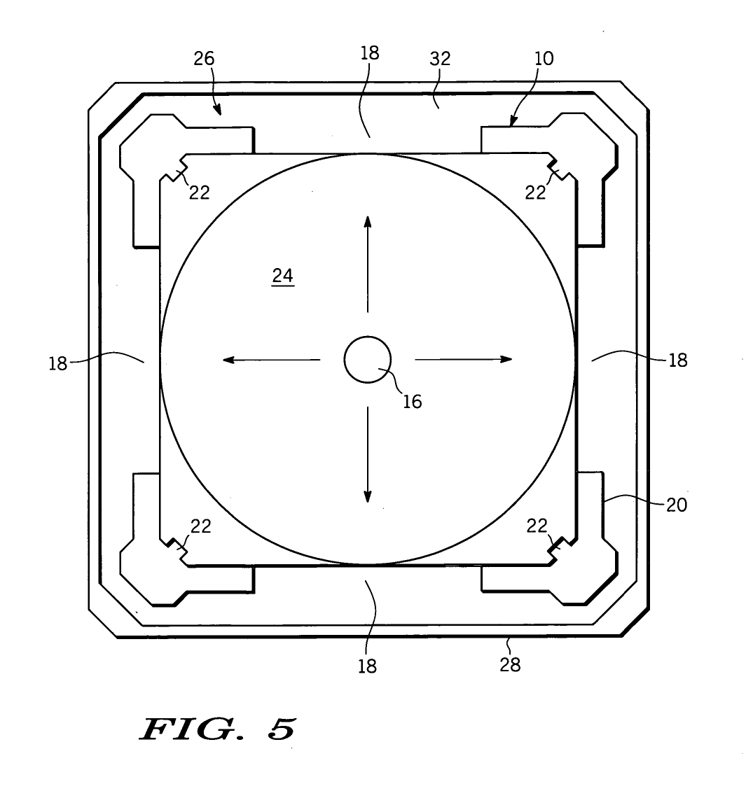

Referring now to FIG. 5, an enlarged cross-sectional view of the semiconductor assembly 26 along the line X-X in FIG. 4 is shown. The mold compound 24 flows radially outwards from its point of entry (i.e. the hole 16) towards the perimeter of the heat sink 10 on entering the space beneath the top surface 12 of the heat sink 10. The air beneath the top surface 12 of the heat sink 10 is displaced by the mold compound 24 and escapes through the gaps 18 along the sides of the heat sink 10 and the vents 22 at the corners of the heat sink 10. Accordingly, the provision of vents 22 at the respective corners of the heat sink 10 prevents trapping of air, thereby reducing the number of voids formed in the resultant semiconductor package. The mold compound 24 also flows through the gaps 18 and over the outside of the side wall 14 and the base 20 to the edges of the mold cavity 28.

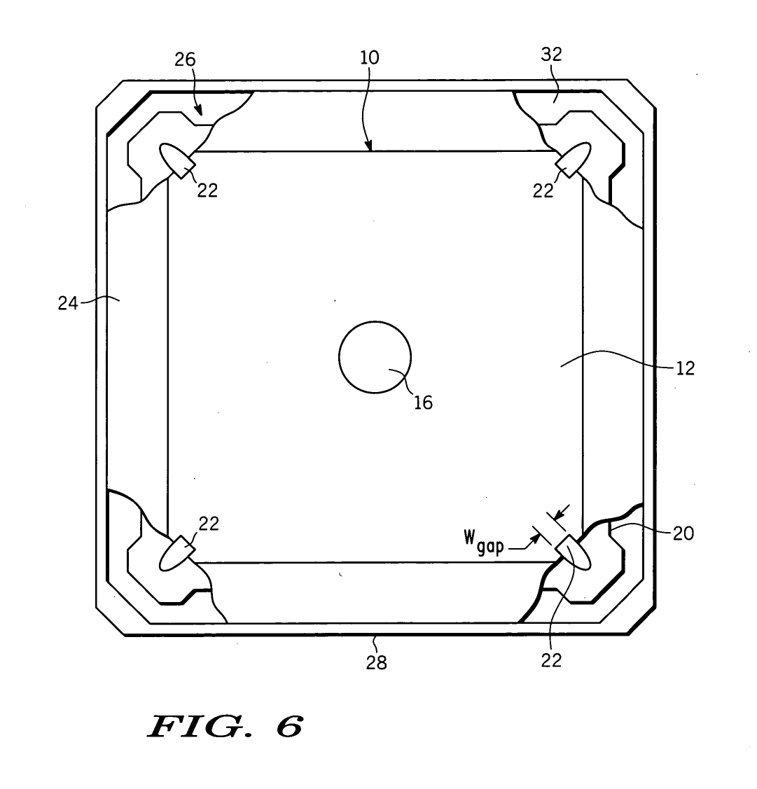

Referring now to FIG. 6, an enlarged top plan view of the semiconductor assembly 26 of FIG. 4 being encapsulated by the molding compound 24 is shown. The bulk of the mold compound 24 flows out from under the heat sink 10 via the gaps 18 along the sides of the heat sink 10. Once out of the heat sink 10, the mold compound 24 flows around the heat sink 10 towards the mold air vents (not shown) located at the corners of the mold cavity 28. The arrangement of the gaps 18 along the sides of the heat sink 10 directs the flow of the mold compound 24 to all parts of the mold cavity 28, while the air vents 22 allow air to escape from beneath the top surface 12, thereby preventing the trapping of air, which reduces the number of voids formed in the resultant semiconductor package. As previously mentioned, the vents 22 are sized to restrict the flow of the mold compound 24 therethrough during encapsulation. The vents 22 are sized in such a way to prevent premature sealing, which occurs if a large quantity of the mold compound 24 is allowed therethrough. In an exemplary embodiment, the vents 22 have a width Wᵥₑₙₜ of about 1.0 to about 1.5 mm.

As can be seen from FIG. 6, the top surface 12 of the heat sink 10 is substantially square in shape. Nonetheless, those of skill in the art will understand that the present invention is not limited by the shape of the top surface 12 of the heat sink 10. In alternative embodiments, the top surface 12 of the heat sink 10 may be rectangular or circular in shape. However, substantially square or rectangular shaped top surfaces 12 are preferred over circular ones as the former shapes provide a larger marking surface, for example, for longer character strings, and a larger exposed surface for the removal of heat, compared to the latter. Apart from providing a larger marking surface and a larger exposed surface for heat removal, a rectangular shaped heat sink 10 also helps in maintaining a consistent rate of flow of the mold compound 24 around the heat sink 10.

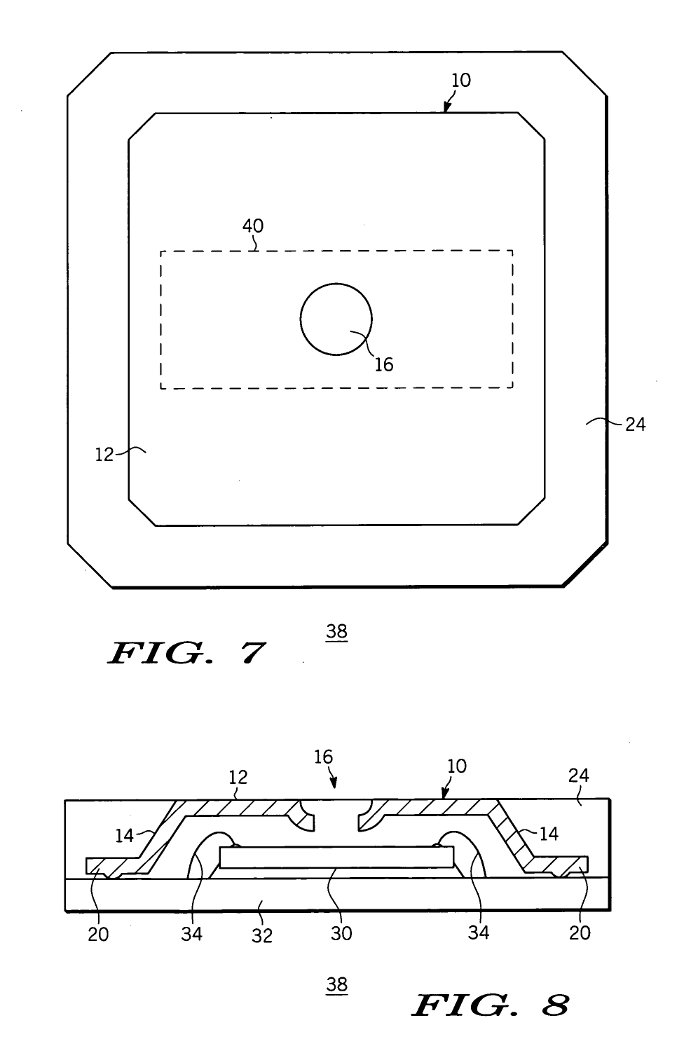

Referring now to FIG. 7, an enlarged top plan view of one embodiment of a semiconductor package 38 formed out of the encapsulated semiconductor assembly 26 of FIG. 6 is shown. As can be seen, the top surface 12 of the heat sink 10 is exposed after the encapsulation. However, because the recessed hole 16 is filled with the mold compound 24, a keep-out zone 40 (defined by dashed lines) is maintained during laser marking to prevent damage to the semiconductor package 38.

Referring now to FIG. 8, an enlarged cross-sectional view of the semiconductor package 38 is shown. As can be seen, the IC die 30, a portion of the substrate 32 and a portion of the heat sink 10 are covered by the mold compound 24. At least the top surface 12 of the heat sink 10 is exposed. During encapsulation, backpressure from the mold compound 24 exerts an upward force on the recessed portion of the top surface 12, which results in a reduction in the size of the hole 16, which inhibits the mold compound 24 from flowing back through the hole 16. Bleeding or flashing of the mold compound 24 is thus reduced as the reduction in the size of the hole 16 serves to retain the mold compound 24 within the mold cavity 28.

As is evident from the foregoing discussion, the present invention provides a heat sink for a center gate molded semiconductor package. In the present invention, a hole is formed proximate to a center of a top surface of the heat sink to facilitate center gate molding. The hole is recessed to reduce bleeding or flashing of the mold compound during encapsulation. The provision of gaps along the sides of the heat sink and at least one vent proximate to a corner of the heat sink serves to direct the flow of the mold compound to all parts of the mold cavity, thereby preventing the trapping of air. This reduces the number of voids formed in the resultant semiconductor package, thereby improving the reliability and yield of such packages. Additionally, the top surface of the heat sink is shaped to provide a larger marking surface and a larger exposed surface for the removal of heat.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For example, the present invention is applicable to over molded packages that are encapsulated by a center gate molding process, including but not limited to OMPAC PBGA, Die Up TBGA and TBGA packages. In addition, the die sizes and the dimensions of the steps may vary to accommodate the required package design. It is understood, therefore, that this invention is not limited to the particular embodiments disclosed, but covers modifications within the spirit and scope of the present invention as defined by the appended claims.

1. A heat sink for a semiconductor package, comprising:
a top surface including a recessed hole proximate to a center thereof; and
at least one vent proximate to a corner of the heat sink.

2. The heat sink of claim 1, wherein the hole facilitates center gate molding.

3. The heat sink of claim 2, wherein the recessed hole reduces bleeding of a mold compound during encapsulation.

4. The heat sink of claim 1, wherein the vent facilitates release of air beneath the top surface of the heat sink.

5. The heat sink of claim 4, wherein the vent is sized to restrict flow of a mold compound therethrough during encapsulation.

6. The heat sink of claim 1, further comprising a sidewall formed around the top surface of the heat sink.

7. The heat sink of claim 6, further comprising a plurality of gaps formed in the sidewall.

8. The heat sink of claim 7, wherein the gaps are formed along respective sides of the heat sink.

9. The heat sink of claim 8, wherein the at least one vent comprises a plurality of vents formed in the respective corners of the heat sink.

10. The heat sink of claim 9, further comprising a base formed at a distal end of the sidewall.

11. The heat sink of claim 1, wherein the top surface is substantially rectangular in shape.

12. The heat sink of claim 1, wherein the heat sink is made of copper.

13. A heat sink for a semiconductor package, comprising:
a top surface including a recessed hole proximate to a center thereof;
a sidewall formed around the top surface;
a plurality of gaps formed in the sidewall; and
at least one vent proximate to a corner of the heat sink.

14. The heat sink of claim 13, wherein the hole facilitates center gate molding.

15. A semiconductor package, comprising:
a substrate;
an integrated circuit (IC) die attached and electrically connected to the substrate; and
a heat sink disposed over the IC die and attached to the substrate, the heat sink comprising:
a top surface including a recessed hole proximate to a center thereof; and
at least one vent proximate to a corner of the heat sink.

16. The semiconductor package of claim 15, wherein the hole facilitates center gate molding.

17. The semiconductor package of claim 15, further comprising a sidewall formed around the top surface of the heat sink.

18. The semiconductor package of claim 17, further comprising a plurality of gaps formed in the sidewall of the heat sink.

19. The semiconductor package of claim 18, further comprising a plurality of vents formed in the respective corners of the heat sink.

20. The semiconductor package of claim 15, further comprising a mold compound covering the IC die, a portion of the substrate and a portion of the heat sink, wherein at least the top surface of the heat sink is exposed.
